(19) United States
(12) Patent Application Publication
(10) Pub. No.: US 2026/0254457 A1
(43) Pub. Date: Aug. 27, 2026

(54) PHASE-LOCKED CIRCUIT, IMAGING DEVICE, AND ELECTRONIC CIRCUIT

(71) Applicant: Sony Semiconductor Solutions Corporation, Kanagawa (JP)

(72) Inventor: Keigo Bunsen, Kanagawa (JP)

(21) Appl. No.: 19/491,195

(22) PCT Filed: May 10, 2024
(86) PCT No.: PCT/JP2024/017484

§ 371 Date: Dec. 8, 2025

(30) Foreign Application Priority Data
Jul. 6, 2023 (JP) 2023-111234

(51) Int. Cl. H03L 7/091; H03L 7/081; H03L 7/099

(52) U.S. Cl. CPC H03L 7/091; H03L 7/0814; H03L 7/0992; H03L 2207/50

(57) ABSTRACT

To make it possible to reduce jitter while suppressing an increase in circuit size of a phase-locked circuit. A phase-locked circuit includes a sample hold circuit configured to sub-sample an input signal, on the basis of a reference signal, a voltage-to-time converter configured to convert a voltage of the input signal sub-sampled by the sample hold circuit into a time difference, and a time-to-digital converter configured to detect the time difference converted by the voltage-to-time converter. The sample hold circuit, the voltage-to-time converter, and the time-to-digital converter may constitute a time domain ADC. The phase-locked circuit may further include a digitally-controlled oscillator configured to generate the input signal.

### TECHNICAL FIELD

The present technology relates to a phase-locked circuit, an imaging device, and an electronic circuit. More specifically, the present technology relates to a phase-locked circuit, an imaging device, and an electronic circuit in which an all digital PLL (ADPLL) is used.

### BACKGROUND ART

In the ADPLL, a phase difference (time difference) between a reference clock and an output signal of a digitally-controlled oscillator (DCO) is detected in a time domain by a time-to-digital converter (TDC). For example, a digital PLL circuit provided with a sample hold circuit that samples the phase difference between the output signal of the DCO and the reference signal as a voltage has been proposed (for example, see PTL 1).

### CITATION LIST

### Patent Literature

PTL 1: JP 2016-140021 A

### SUMMARY OF INVENTION

### Technical Problem

However, in the above-described technology of the related art, sub-sampling using an analog-to-digital converter (ADC) is performed in order to reduce jitter. Therefore, the above-described technology of the related art may lead to an increase in circuit size and power consumption.

The present technology has been made in view of such circumstances, and an object thereof is to make it possible to reduce jitter while suppressing an increase in circuit size of a phase-locked circuit.

### Solution to Problem

The present technology has been made to solve the problem described above, and a first aspect of the present technology is a phase-locked circuit including a sample hold circuit configured to sub-sample an input signal, on the basis of a reference signal, a voltage-to-time converter configured to convert a voltage of the input signal sub-sampled by the sample hold circuit into a time difference, and a time-to-digital converter configured to detect the time difference converted by the voltage-to-time converter. Accordingly, an effect in that the time resolution of the input signal is set on the basis of the voltage resolution of the input signal is obtained.

Further, in the first aspect, the sample hold circuit, the voltage-to-time converter, and the time-to-digital converter may constitute a time domain analog to digital converter (ADC). Accordingly, an effect in that the time resolution of the input signal is set on the basis of AD is obtained.

Further, in the first aspect, a time resolution of the time domain ADC may be higher than a time resolution of the time-to-digital converter. Accordingly, an effect in that jitter caused by the restriction of the time resolution of the time-to-digital converter is reduced is obtained.

Further, the first aspect may further include a digitally-controlled oscillator configured to generate the input signal. Accordingly, an effect in that the frequency of the input signal is adjusted on the basis of control of a digital code to be input to the digitally-controlled oscillator voltage is obtained.

Further, the first aspect may further include an accumulator configured to set a count-up value for each cycle of the reference signal, on the basis of a frequency command word (FCW), a counter configured to count up for each cycle of the input signal, an arithmetic unit configured to subtract an output of the counter and an output of the time-to-digital converter from an output of the accumulator, and a loop filter configured to limit a band of an input to the digitally-controlled oscillator. Accordingly, an effect in that a phase-locked loop using the time domain ADC is formed is obtained.

Further, the first aspect may further include a frequency divider configured to frequency-divide the input signal generated by the digitally-controlled oscillator. Accordingly, an effect in that the frequency-divided input signal is input to the time domain ADC is obtained.

Further, the first aspect may further include a digital-to-time converter configured to delay the reference signal. Accordingly, an effect in that a phase shift corresponding to a fraction in a fractional phase-locked loop (PLL) is adjusted is obtained.

Further, the first aspect may further include a selector configured to switch an input to the time-to-digital converter, between an input of the time difference converted by the voltage-to-time converter and an input of the reference signal and the input signal. Accordingly, an effect of achieving both expansion of a lock range of the phase-locked circuit and improvement of the time resolution in a compatible manner is obtained.

Further, in the first aspect, the selector may input the time difference converted by the voltage-to-time converter to the time-to-digital converter when a sub-sampling mode is specified, and may input the reference signal and the input signal to the time-to-digital converter when a normal mode is specified. Accordingly, an effect in that the mode is switched between the sub-sampling mode and the normal mode is obtained.

Further, in the first aspect, the normal mode may be intermittently operated during operation in the sub-sampling mode. Accordingly, an effect of improving the time resolution while achieving stabilization of phase locking is obtained.

Further, in the first aspect, calibration of a phase-locked loop may be performed. Accordingly, an effect in that the stabilization of the phase locking is improved is obtained.

A second aspect is an imaging device including an imaging section including a plurality of pixels and a phase-locked circuit configured to generate a clock signal for setting an operation timing of the imaging section. The phase-locked circuit includes a sample hold circuit configured to sub-sample the clock signal, on the basis of a reference clock, a voltage-to-time converter configured to convert a voltage of the clock signal sub-sampled by the sample hold circuit into a time difference, and a time-to-digital converter configured to detect the time difference converted by the voltage-to-time converter. Accordingly, an effect in that the time resolution of the clock signal is set on the basis of the voltage resolution of the clock signal used for the imaging device is obtained.

A third aspect is an electronic circuit including a circuit unit configured to operate on the basis of a clock signal and a phase-locked circuit configured to generate a clock signal for setting an operation timing of the circuit unit. The phase-locked circuit includes a sample hold circuit configured to sub-sample the clock signal, on the basis of a reference clock, a voltage-to-time converter configured to convert a voltage of the clock signal sub-sampled by the sample hold circuit into a time difference, and a time-to-digital converter configured to detect the time difference converted by the voltage-to-time converter. Accordingly, an effect in that the time resolution of the clock signal is set on the basis of the voltage resolution of the clock signal used for the electronic circuit is obtained.

### BRIEF DESCRIPTION OF DRAWINGS

FIG. 1 is a block diagram depicting a configuration example of a phase-locked circuit according to a first embodiment.

FIG. 2 is a timing chart depicting waveforms of respective sections of the phase-locked circuit according to the first embodiment.

FIG. 3 depicts timing charts each depicting a relationship between a clock signal and a reference clock of the phase-locked circuit according to the first embodiment.

FIG. 4 is a diagram showing a first example of a relationship between an offset frequency and phase noise of the phase-locked circuit according to the first embodiment.

FIG. 5 is a diagram showing a second example of the relationship between the offset frequency and the phase noise of the phase-locked circuit according to the first embodiment.

FIG. 6 is a diagram depicting a configuration example of a time-to-digital converter according to the first embodiment.

FIG. 7 depicts diagrams each depicting a configuration example of the digital-to-time converter according to the first embodiment.

FIG. 8 is a diagram depicting a configuration example of the digital-to-time converter according to the first embodiment.

FIG. 9 is a flowchart depicting an operation of the phase-locked circuit according to the first embodiment.

FIG. 10 is a flowchart depicting an operation of a phase-locked circuit according to a second embodiment.

FIG. 11 is a block diagram depicting a configuration example of a phase-locked circuit according to a third embodiment.

FIG. 12 is a flowchart depicting an operation of the phase-locked circuit according to the third embodiment.

FIG. 13 is a block diagram depicting a configuration example of a phase-locked circuit according to a fourth embodiment.

FIG. 14 is a block diagram depicting a configuration example of a phase-locked circuit according to a fifth embodiment.

FIG. 15 is a block diagram depicting a configuration example of an imaging device to which a phase-locked circuit according to a sixth embodiment is applied.

FIG. 16 is a block diagram depicting a configuration example of a solid-state imaging device according to the sixth embodiment.

FIG. 17 is a perspective view depicting a layering example of a pixel array section according to a seventh embodiment.

FIG. 18 is a block diagram depicting a schematic configuration example of a vehicle control system.

FIG. 19 is an explanatory view depicting an example of an installation position of an imaging section.

### DESCRIPTION OF EMBODIMENTS

Hereinafter, modes (hereinafter, referred to as embodiments) for implementing the present technology will be described. The description will be made in the following order.
1. First Embodiment (an example in which a voltage of a clock signal sub-sampled by a sample hold circuit is converted into a time difference by a voltage-to-time converter, and the time difference is detected by a time-to-digital converter)
2. Second Embodiment (an example in which calibration of a phase-locked loop is performed after mode setting)
3. Third Embodiment (an example in which an operation is performed only in a sub-sampling mode)
4. Fourth Embodiment (an example in which a reference clock is input to a selector without being through a digital-to-time converter)
5. Fifth Embodiment (an example in which a clock signal output from a digitally-controlled oscillator is frequency-divided)
6. Sixth Embodiment (an example in which a phase-locked circuit is applied to an imaging device)
7. Seventh Embodiment (an example in which a pixel array section is layered)
8. Application Example to Mobile Body

### 1. First Embodiment

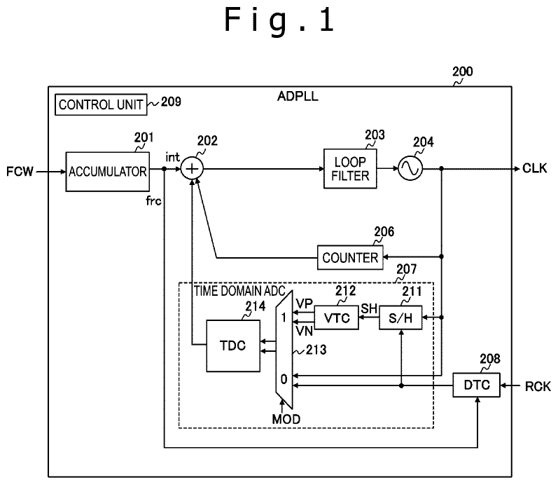

FIG. 1 is a block diagram depicting a configuration example of a phase-locked circuit according to a first embodiment.

In this diagram, an ADPLL 200 is provided as the phase-locked circuit. The ADPLL 200 forms a feedback loop on the basis of phase locking, and outputs a clock signal CLK. The frequency of the clock signal CLK can be determined on the basis of a frequency command word (FCW). The FCW can specify a ratio of the frequency of the clock signal CLK to the frequency of a reference clock RCK. The FCW can include an integer int and a fraction frc. The FCW can be provided from outside the ADPLL 200. The ADPLL 200 includes an accumulator 201, an arithmetic unit 202, a loop filter 203, a digitally-controlled oscillator 204, a counter 206, a time domain ADC 207, a digital-to-time converter 208, and a control unit 209.

The digitally-controlled oscillator 204 generates the clock signal CLK on the basis of an oscillation operation. The digitally-controlled oscillator 204 can change an oscillation frequency on the basis of an oscillator tuning word. The digitally-controlled oscillator 204 may be a ring oscillator or an LC oscillator.

The counter 206 counts up for each clock of the clock signal CLK, and outputs the count value to the arithmetic unit 202. At this time, the counter 206 can detect the phase in units of one cycle of the clock signal CLK.

The accumulator 201 sets a count-up value for each cycle of the reference clock RCK on the basis of the FCW, and outputs the count-up value to the arithmetic unit 202. At this time, the FCW is input to the accumulator 201. Then, the accumulator 201 can output the integer int specified by the FCW to the arithmetic unit 202 and output the fraction frc specified by the FCW to the digital-to-time converter (DTC) 208.

The arithmetic unit 202 subtracts the output of the counter 206 and the output of a time-to-digital converter 214 from the output of the accumulator 201, and outputs the result to the loop filter 203. The output of the arithmetic unit 202 can indicate a phase error between the reference clock RCK and the clock signal CLK. At this time, the ADPLL 200 can operate a phase-locked loop so that the phase difference approaches zero.

The loop filter 203 limits the band of the input to the digitally-controlled oscillator 204 and reduces the influence of a quantization error. Gain of the loop filter 203 can be adjusted on the basis of calibration of the ADPLL 200.

The digital-to-time converter 208 delays the reference clock RCK and outputs the delayed reference clock RCK to a sample hold circuit 211 and a selector 213. Here, in a fractional PLL, a phase shift occurs by a fraction each time the clock signal CLK is sub-sampled on the basis of the reference clock RCK. Since the value of the phase shift is known, the digital-to-time converter 208 can set a delay time so that the phase shift is corrected. By correcting the phase shift by the digital-to-time converter 208, it is possible to eliminate the need to expand the range of the time-to-digital converter 214 corresponding to the phase shift. Therefore, the time-to-digital converter 214 may have a relatively narrow range to which a margin for coping with the resolution of the digital-to-time converter 208, jitter of the digitally-controlled oscillator 204, and other errors is added. Note that in an integer PLL, the digital-to-time converter 208 is not necessary.

The time domain ADC 207 performs AD conversion in a time domain. The time resolution of the time domain ADC 207 may be higher than the time resolution of the time-to-digital converter 214. The time domain ADC 207 includes the sample hold circuit 211, a voltage-to-time converter 212, the selector 213, and the time-to-digital converter 214.

The sample hold circuit 211 sub-samples the clock signal CLK on the basis of the reference clock RCK. Then, the sample hold circuit 211 holds a sub-sampled sample hold value SH and outputs the sample hold value SH to the voltage-to-time converter (VTC) 212.

The voltage-to-time converter 212 converts the voltage of the clock signal CLK sub-sampled by the sample hold circuit 211 into a time difference. At this time, the voltage-to-time converter 212 can set a time difference between the rises of output voltages VP and VN, on the basis of the sample hold value SH held in the sample hold circuit 211.

The selector 213 switches an input to the time-to-digital converter 214 between an input of the time difference converted by the voltage-to-time converter 212 and an input of the reference clock RCK and the clock signal CLK. Here, the selector 213 can switch between a sub-sampling mode and a normal mode on the basis of a mode setting signal MOD. At this time, in the sub-sampling mode, the selector 213 inputs the time difference converted by the voltage-to-time converter 212 to the time-to-digital converter 214. In the normal mode, the selector 213 inputs the reference clock RCK and the clock signal CLK to the time-to-digital converter 214.

In the sub-sampling mode, the time-to-digital converter (TDC) 214 detects the time difference converted by the voltage-to-time converter 212, digitizes the time difference, and outputs the digitized time difference to the arithmetic unit 202. In the sub-sampling mode, the time difference to be detected by the time-to-digital converter 214 is expanded and input. In the normal mode, the time-to-digital converter 214 detects a time difference between the reference clock RCK and the clock signal CLK, digitizes the time difference, and outputs the digitized time difference to the arithmetic unit 202. The time-to-digital converter 214 may be a delay line TDC.

The time difference detected by the time-to-digital converter 214 is expanded on the basis of gain from the input of the sample hold circuit 211 to the input of the time-to-digital converter 214. The gain from the input of the sample hold circuit 211 to the input of the time-to-digital converter 214 can be given as follows.

When the clock signal CLK is a sine wave having an amplitude Vck [V] and a frequency fck [Hz], the slope near the zero cross is 2π·fck·Vck. Therefore, voltage gain with respect to a time lag Δtck of the clock signal CLK is 2π·fck·Vck·Δtck. Further, gain TG of the voltage-to-time converter 212 is a designed value, and for example, 200 [psec] or the like can be realized with the input of 100 mV.

When Vck=1 [V] and fck=2 [GHz] are used as standard values, gain from the time lag Δtck at the input of the sample hold circuit 211 to a time lag Δtvo at the output of the voltage-to-time converter 212 can be given by the following equation.

$$Δ tvo = 2 Π \cdot fck \cdot Vck \cdot Δ tck [ V / sec ] \cdot TG [ sec / V ] = 2 Π \cdot 2 \cdot {10}^{9} \cdot Δ tck \cdot 200 p / 100 m$$

$$Δ tvo / Δ tck = 25.1$$

That is, by interposing the sample hold circuit 211 and the voltage-to-time converter 212 at stages preceding the time-to-digital converter 214, gain is provided in the time domain, and the time lag near the zero cross of the clock signal CLK is expanded by 25.1 times and input to the time-to-digital converter 214. When the time resolution is input-converted, the input-converted time resolution is about 0.8 psec when the TDC time resolution is 20 psec, and the time resolution is equivalently improved.

The control unit 209 integrally controls the ADPLL 200. For example, the control unit 209 can control an operation sequence of the ADPLL 200, supply an enable signal at the time of activation of the ADPLL 200, perform mode switching of the ADPLL 200, and set a coefficient of the loop filter 203.

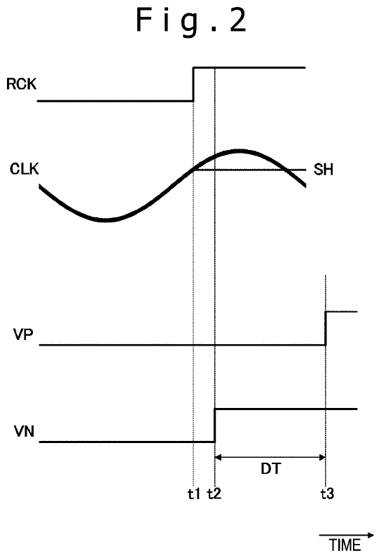

FIG. 2 is a timing chart depicting waveforms of respective sections of the phase-locked circuit according to the first embodiment.

In FIG. 2, when the reference clock RCK rises (t1), the sample hold circuit 211 sub-samples the clock signal CLK and holds the sample hold value SH.

Then, the voltage-to-time converter 212 raises the output voltage VN on the basis of the sample hold value SH held in the sample hold circuit 211 (t2). Subsequently, the voltage-to-time converter 212 raises the output voltage VP after a time difference DT corresponding to the sample hold value SH has elapsed (t3). The time difference DT may be proportional to the sample hold value SH.

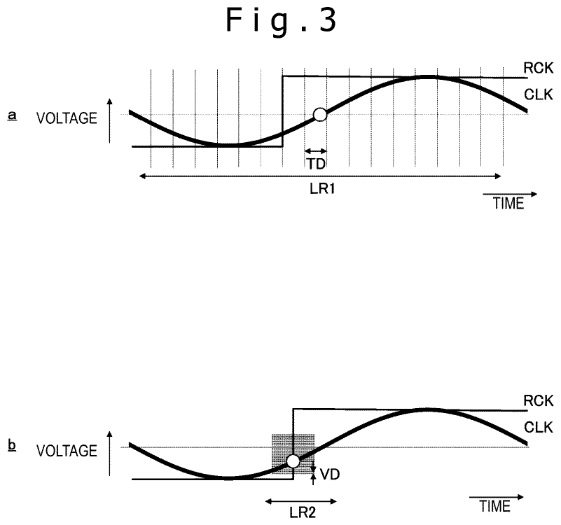

FIG. 3 depicts timing charts each depicting a relationship between the clock signal and the reference clock of the phase-locked circuit according to the first embodiment. Note that a of FIG. 3 depicts an operation example in the normal mode. Further, b of FIG. 3 depicts an operation example in the sub-sampling mode.

In a of FIG. 3, in the normal mode, the time-to-digital converter 214 detects the time difference between the reference clock RCK and the clock signal CLK. At this time, as the TDC time resolution, for example, the value of 20 psec can be obtained.

In the normal mode, the time difference between the reference clock RCK and the clock signal CLK is directly detected. Therefore, in the normal mode, the time difference between the reference clock RCK and the clock signal CLK is not affected by the cycle of the clock signal CLK, and a wide lock range LR1 can be secured.

In b of FIG. 3, in the sub-sampling mode, the voltage-to-time converter 212 converts the voltage VD of the clock signal CLK sub-sampled by the sample hold circuit 211 into a time difference. At this time, as the time resolution, for example, the value of 0.8 psec can be obtained. For example, it is assumed that the gain TG of the voltage-to-time converter 212 is 200 psec/100 mV. At this time, the voltage resolution of the voltage-to-time converter 212 is TDC time resolution/TG=10 mV. When the clock signal CLK is a sine wave, the value of 10 mV/2πf [V/sec]=0.8 psec can be obtained as the time resolution of the time domain ADC 207.

In the sub-sampling mode, the voltage VD of the clock signal CLK is converted into the time difference. Therefore, in the sub-sampling, the time difference between the reference clock RCK and the clock signal CLK is affected by the cycle of the clock signal CLK, and a lock range LR2 becomes narrow. This lock range LR2 is limited to being within ±π/4 rad.

Therefore, to achieve both expansion of the lock range of the phase-locked circuit and improvement of the time resolution in a compatible manner, it is effective to switch between the sub-sampling mode and the normal mode. For example, the normal mode may be operated intermittently during operation in the sub-sampling mode.

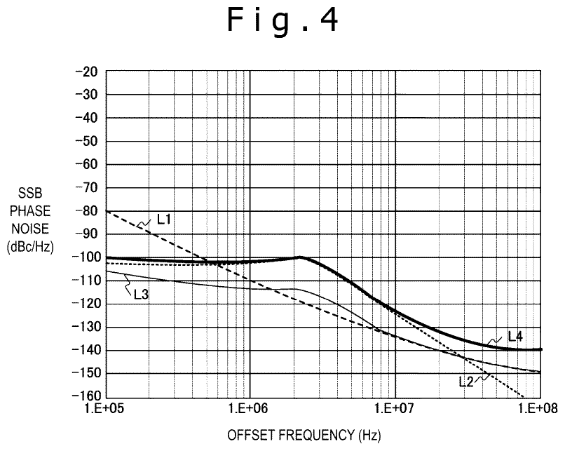

FIG. 4 is a diagram showing a first example of a relationship between an offset frequency and phase noise of the phase-locked circuit according to the first embodiment. Note that this drawing shows the relationship between the offset frequency and the phase noise in the normal mode. L1 indicates phase noise of OL-DCO, L2 indicates phase noise of TDC, L3 indicates phase noise of DCO, and L4 indicates the total phase noise.

In this drawing, when the TDC time resolution is 20 psec, the contribution of quantization noise of the time-to-digital converter 214 to jitter of the ADPLL 200 is large, and the jitter is 1.8 psec.

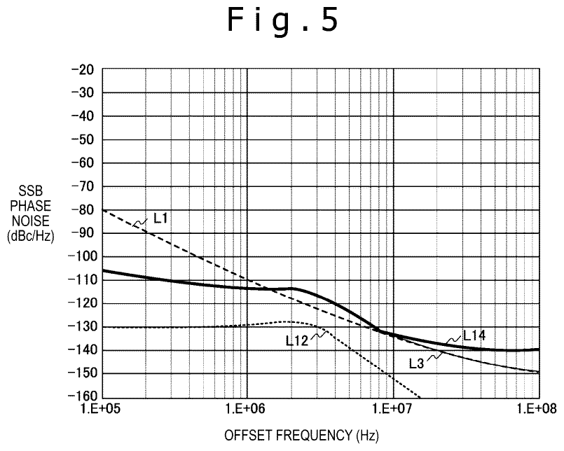

FIG. 5 is a diagram showing a second example of the relationship between the offset frequency and the phase noise of the phase-locked circuit according to the first embodiment. Note that this drawing shows the relationship between the offset frequency and the phase noise in the sub-sampling mode.

In FIG. 5, if the TDC time resolution is 0.8 psec, the quantization noise of the time-to-digital converter 214 becomes smaller than other noises by about 10 dB or more, and is no longer the dominant term. Thus, the jitter of the ADPLL 200 is reduced to 0.6 psec.

Since the normal mode has the wide lock range LR1 and is robust, by performing various calibrations immediately after the activation in the normal mode and then switching the mode to the sub-sampling mode, the activation can be performed safely. Although the normal mode has larger jitter than the sub-sampling mode, since the normal mode is robust and consumes less power, an appropriate mode can be selected in accordance with an application. Further, by inserting the normal mode between the sub-sampling modes, it is possible to prevent a cycle slip during the sub-sampling operation and to achieve both the expansion of the lock range and the improvement of the time resolution in a compatible manner.

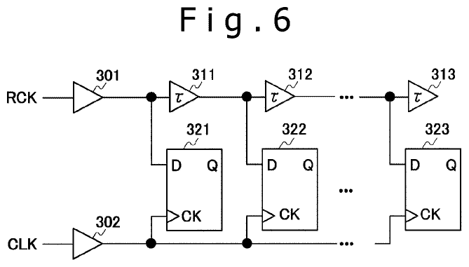

FIG. 6 is a diagram depicting a configuration example of the time-to-digital converter according to the first embodiment. Note that, in this drawing, an example in which the time-to-digital converter 214 is the delay line TDC is depicted.

In FIG. 6, the time-to-digital converter 214 includes delay buffers 311 to 313 and flip-flops 321 to 323. The reference clock RCK is input via the buffer 301, delayed by an integral multiple of a buffer delay t by the delay buffers 311 to 313, and input to the D terminals of the flip-flops 321 to 323, respectively.

The clock signal CLK is input to a CK terminal of each of the flip-flops 321 to 323 via a buffer 302. At this time, each of the flip-flops 321 to 323 fetches the state of the reference clock RCK of the delay line at the rise of the clock signal CLK. As a result, it is possible to measure how many multiples of the buffer delay a time interval up to the rise of the clock signal CLK corresponds to, and convert the time into a digital value. In this configuration, the buffer delay τ on the path of the reference clock RCK is the minimum time resolution.

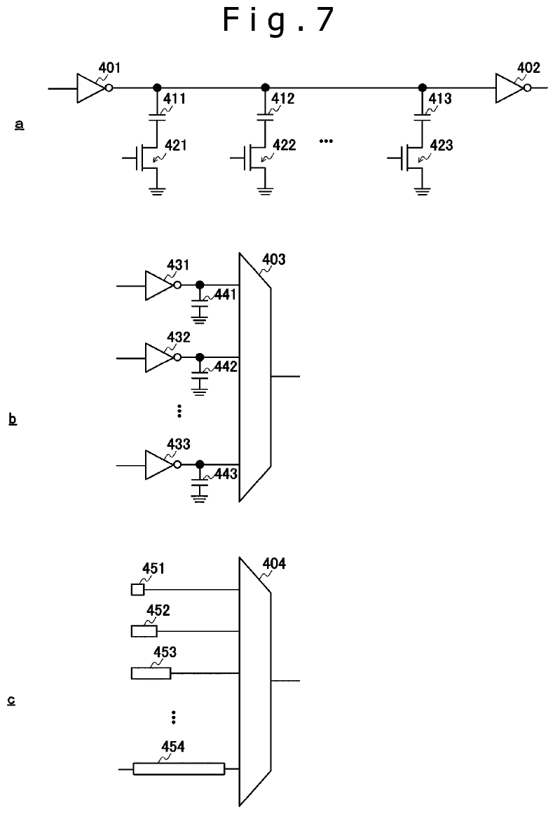

FIG. 7 depicts diagrams each depicting a configuration example of the digital-to-time converter according to the first embodiment. Note that a of FIG. 7 depicts a first example of the digital-to-time converter 208, b of FIG. 7 depicts a second example of the digital-to-time converter 208, and c of FIG. 7 depicts a third example of the digital-to-time converter 208.

In a of FIG. 7, the first example of the digital-to-time converter 208 includes inverters 401 and 402, capacitors 411 to 413, and field effect transistors 421 to 423. The inverters 401 and 402 are connected in series to each other. The capacitors 411 to 413 are connected in series to the field effect transistor 421 to 423, respectively. Respective series circuits from the capacitors 411 to 413 to the field effect transistors 421 to 423 are connected in parallel between the inverters 401 and 402. The respective series circuits from the capacitors 411 to 413 to the field effect transistors 421 to 423 can be operated as a variable capacitance.

In b of FIG. 7, the second example of the digital-to-time converter 208 includes inverters 431 to 433, capacitors 441 to 443, and a selector 403. The capacitors 441 to 443 are connected in parallel to the outputs of the inverters 431 to 433, respectively. Respective parallel circuits from the inverters 431 to 433 to the capacitors 441 to 443 can have different delay amounts. The selector 403 can select any of the outputs of the inverters 431 to 433.

In c of FIG. 7, the third example of the digital-to-time converter 208 includes wiring lines 451 to 454 and a selector 404. The wiring lines 451 to 454 can have different propagation delays. The selector 404 can select any of the wiring lines 451 to 454.

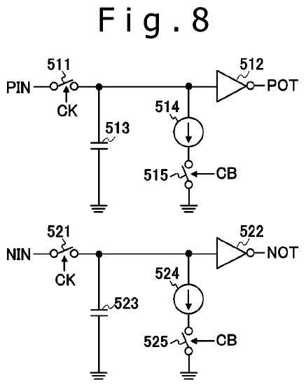

FIG. 8 is a diagram depicting a configuration example of the digital-to-time converter according to the first embodiment.

In this drawing, the digital-to-time converter 208 includes switches 511, 521, 515, and 525, inverters 512 and 522, capacitors 513 and 523, and current sources 514 and 524. The switch 511 is connected in series to the inverter 512. The switch 521 is connected in series to the inverter 522. The current source 514 is connected in series to the switch 515. The current source 524 is connected in series to the switch 525. The capacitor 513 and a series circuit of the current source 514 and the switch 515 are connected in parallel between the switch 511 and the inverter 512. The capacitor 523 and a series circuit of the current source 524 and the switch 525 are connected in parallel between the switch 521 and the inverter 522. Each of the switches 511 and 521 is turned on/off on the basis of a clock CL. Each of the switches 515 and 525 is turned on/off on the basis of an inverted clock CB. The inverted clock CB is a signal obtained by inverting the clock CL. At this time, inputs PIN and NIN are input via the switches 511 and 521, respectively, and outputs POT and NOT are output via the inverters 512 and 522, respectively.

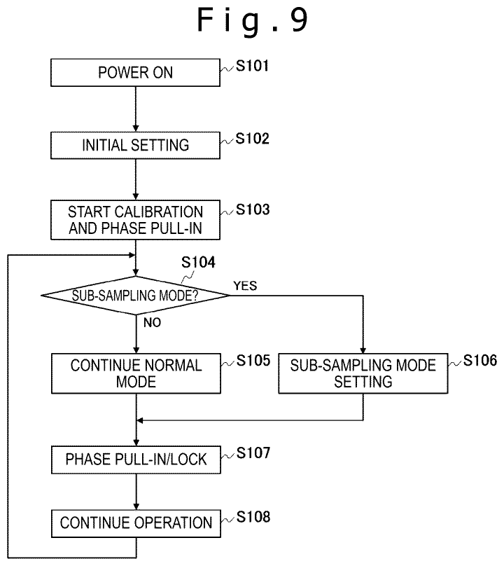

FIG. 9 is a flowchart depicting an operation of the phase-locked circuit according to the first embodiment.

In this drawing, when the ADPLL 200 is powered on (S101), initial setting of the ADPLL 200 is performed (S102).

Subsequently, calibration and phase pull-in of the ADPLL 200 are started (S103). In the calibration, when a normal path and a sub-sampling path are switched, gain of the normal path and gain of the sub-sampling path are detected and reflected on the loop filter in order to prevent an operation failure and to maintain low jitter while maintaining loop gain constant. As a method for detecting each gain, the following method can be used.

When the gain of the digital-to-time converter 208 is estimated, a correlation value between the output of the time-to-digital converter 214 and the input of the digital-to-time converter 208 is used to detect an error, and a delay amount (time) with respect to an input code of the digital-to-time converter 208 can be obtained. In the estimation of the gain of the digital-to-time converter 208, a method disclosed in the following document may be used.

“Y.-H. Liu et al., “An Ultra-Low Power 1.7 to 2.7 GHZ Fractional-N Sub-Sampling Digital Frequency Synthesizer and Modulator for IoT Applications in 40 nm CMOS,” in IEEE Transactions on Circuits and Systems I: Regular Papers, vol. 64, no. 5, pp. 1094 to 1105 May 2017, doi: 10.1109/TCSI. 2016.2625462.”

With respect to the gain of the normal path, a DTC input code with respect to a TDC1 code can be obtained by shifting the DTC input code and comparing the shift amount with a change amount of a TDC output code. Since the relationship between the DTC input code and the time is known, the time corresponding to the TDC1 code can be determined.

As with the gain of the normal path, with respect to the gain of the sub-sampling path also, a time corresponding to the TDC1 code can be obtained by combining the sample hold circuit 211, the voltage-to-time converter 212, and the time-to-digital converter 214.

Subsequently, the ADPLL 200 determines whether the sub-sampling mode is specified (S104). When the sub-sampling mode is not specified, the ADPLL 200 continues the operation in the normal mode (S105). On the other hand, when the sub-sampling mode is specified, the ADPLL 200 sets the sub-sampling mode (S106).

By switching between the normal mode and the sub-sampling mode, the low robustness of the sub-sampling mode can be compensated. In the normal mode, even when the phase of the clock signal CLK is greatly shifted due to an unexpected movement, disturbance, or the like, the phase shift can be measured as long as the phase shift is within a detection range of the time-to-digital converter 214, and the operation can be returned to a normal operation. For example, in the calibration immediately after the activation, it is not known how much the frequency of the digitally-controlled oscillator 204 is to be changed with respect to an adjustment amount, and thus the phase may be shifted more than assumed. Even in such a case, when the detection range of the time-to-digital converter 214 is designed to be wide, appropriate control is possible. The same effect can be obtained for unexpected disturbance.

On the other hand, in the case of the sub-sampling mode, since the phase is detected on the basis of the slope of the sine wave, when the phase is shifted by +90 degrees or more with respect to the clock signal CLK, the slope is inverted and the control becomes impossible. Therefore, the operation is performed in the normal mode at the time of activation and by the ADPLL 200 performing the calibration, the activation can be performed safely. Thereafter, by performing a low-jitter operation in the sub-sampling mode, both the robustness and the low-jitter operation can be achieved in a compatible manner.

Even during the operation in the sub-sampling mode, by intermittently performing the normal mode operation, it is possible to secure the robustness by detecting the phase using the wide range in the normal mode, in response to the problem in that the cycle slip may occur in the input due to disturbance or the like.

Subsequently, the ADPLL 200 performs phase pull-in and locking (S107), and the operation is continued (S108). Here, the ADPLL 200 can return to S104 while continuing the operation and can determine whether the sub-sampling mode is specified.

As described above, in the first embodiment described above, the voltage of the clock signal CLK sub-sampled by the sample hold circuit 211 is converted into the time difference by the voltage-to-time converter 212, and the time difference is detected by the time-to-digital converter TDC. As a result, the time resolution of the clock signal CLK can be set on the basis of the voltage resolution of the clock signal CLK. At this time, the time difference detected by the time-to-digital converter 214 can be expanded by converting the voltage of the clock signal CLK into the time difference. Therefore, the time resolution of the ADPLL 200 can be improved while coping with the restriction of the TDC time resolution. At this time, by providing the sample hold circuit 211 and the voltage-to-time converter 212 in the time domain ADC 207, it is possible to eliminate the need for sub-sampling using an ADC in order to expand the time difference detected by the time-to-digital converter 214. Therefore, it is possible to reduce jitter while suppressing an increase in circuit size and power consumption of the phase-locked circuit.

In addition, by making it possible to switch between the normal mode and the sub-sampling mode, it is possible to achieve the reduction in jitter by the sub-sampling mode while securing the robustness by the normal mode.

### 2. Second Embodiment

In the first embodiment described above, the calibration of the phase-locked loop is performed before mode setting. In the second embodiment, the calibration of the phase-locked loop is performed after the mode setting.

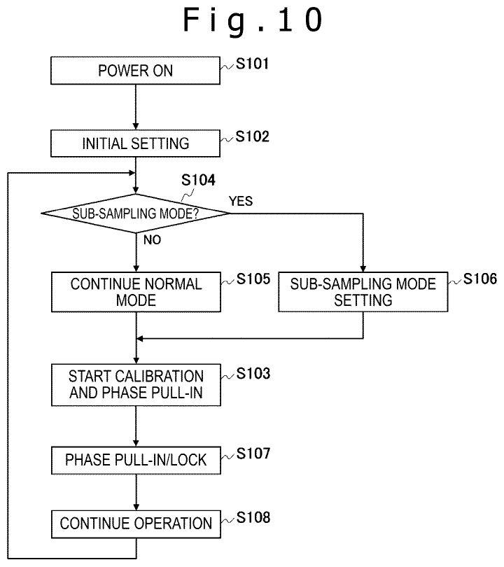

FIG. 10 is a flowchart depicting an operation of a phase-locked circuit according to a second embodiment.

In this flow of FIG. 10, the calibration and phase pull-in of the ADPLL 200 are started (S103) after mode setting (S105, S106). The other flow of the second embodiment is similar to the flow of the first embodiment described above. Here, by performing the calibration after the mode setting, the calibration can be performed while the normal mode is continued, and thus the calibration can be stabilized.

As described above, in the second embodiment, by performing the calibration of the phase-locked loop after the mode setting, the stabilization of the calibration can be achieved.

### 3. Third Embodiment

In the first embodiment described above, the sub-sampling mode and the normal mode can be switched via the selector 213. In the third embodiment, the selector 213 is removed, and the phase-locked circuit is operated only in the sub-sampling mode.

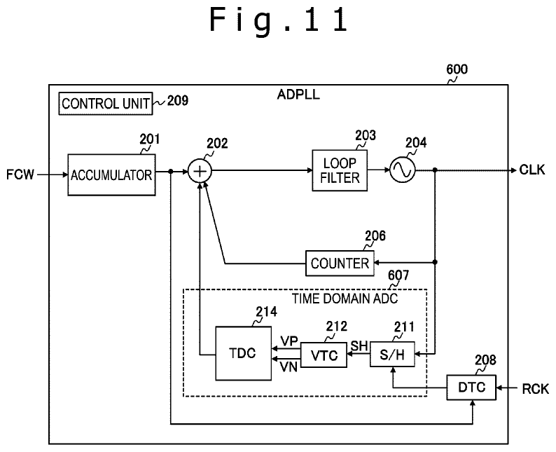

FIG. 11 is a block diagram depicting a configuration example of a phase-locked circuit according to a third embodiment.

In FIG. 11, an ADPLL 600 includes a time domain ADC 607 instead of the time domain ADC 207 of the first embodiment described above. Other configurations of the ADPLL 600 of the third embodiment are similar to the configurations of the ADPLL 200 of the first embodiment described above.

The time domain ADC 607 is obtained by removing the selector 213 from the time domain ADC 207 of the first embodiment described above. At this time, the clock signal CLK is input to the sample hold circuit 211, and the reference clock RCK is input to the sample hold circuit 211 via the digital-to-time converter 208. The output voltages VP and VN of the voltage-to-time converter 212 are input to the time-to-digital converter 214. At this time, the ADPLL 600 can operate only in the sub-sampling mode. Other configurations of the time domain ADC 607 of the third embodiment are similar to the configurations of the time domain ADC 207 of the first embodiment described above.

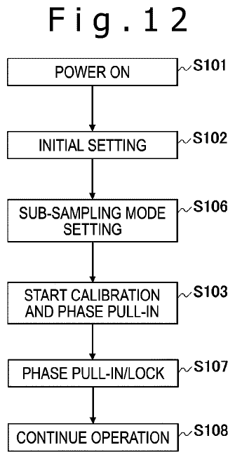

FIG. 12 is a flowchart depicting an operation of the phase-locked circuit according to the third embodiment.

In FIG. 12, the processing of S104 and S105 of the second embodiment is omitted in this flow. At this time, after the initial setting (S102), the sub-sampling mode is set (S106), and the calibration and phase pull-in are started (S103).

As described above, in the third embodiment, the phase-locked circuit is operated only in the sub-sampling mode. As a result, it is possible to eliminate the need for the selector 213 and the need for mode switching control, and thus the circuit size can be reduced while simplifying the control.

### 4. Fourth Embodiment

In the first embodiment described above, the reference clock RCK is input to the selector 213 via the digital-to-time converter 208. In this fourth embodiment, the reference clock RCK is input to the selector 213 without being through the digital-to-time converter 208.

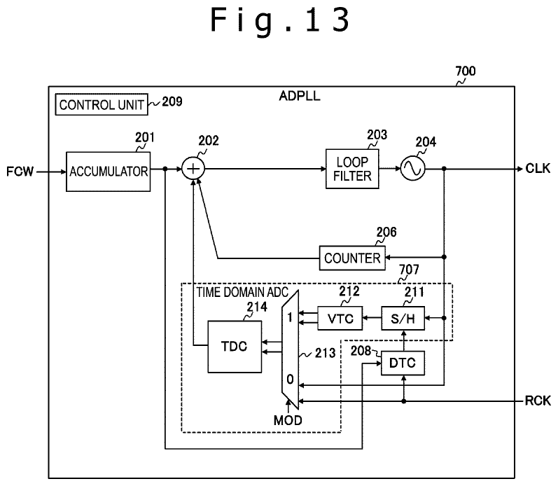

FIG. 13 is a block diagram depicting a configuration example of a phase-locked circuit according to the fourth embodiment.

In this drawing, an ADPLL 700 operates as an integer PLL. The ADPLL 700 is provided with a time domain ADC 707 instead of the time domain ADC 207 of the first embodiment described above. Other configurations of the ADPLL 700 of the fourth embodiment are similar to the configurations of the ADPLL 200 of the first embodiment described above.

In the time domain ADC 707, the reference clock RCK is input to the selector 213 without being through the digital-to-time converter 208. Other configurations of the time domain ADC 707 of the fourth embodiment are similar to the configurations of the time domain ADC 207 of the first embodiment described above.

As described above, in the fourth embodiment, by inputting the reference clock RCK to the selector 213 without being through the digital-to-time converter 208, the reference clock RCK can be directly input to the selector 213.

### 5. Fifth Embodiment

In the first embodiment described above, the clock signal CLK output from the digitally-controlled oscillator 204 is input to the time domain ADC 207. In a fifth embodiment, the clock signal CLK output from the digitally-controlled oscillator 204 is frequency-divided and then input to the time domain ADC 207.

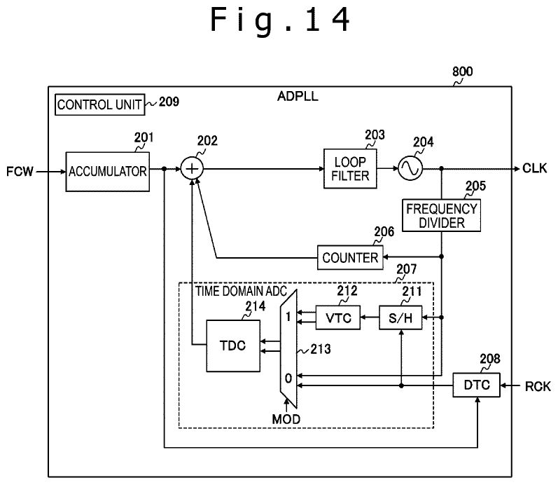

FIG. 14 is a block diagram depicting a configuration example of a phase-locked circuit according to the fifth embodiment.

In this drawing, an ADPLL 800 is obtained by adding a frequency divider 205 to the ADPLL 800 of the first embodiment. Other configurations of the ADPLL 800 of the fifth embodiment are similar to the configurations of the ADPLL 200 of the first embodiment described above.

The frequency divider 205 is connected to a stage subsequent to the digitally-controlled oscillator 204. At this time, the frequency divider 205 frequency-divides the clock signal CLK generated by the digitally-controlled oscillator 204, and outputs the frequency-divided clock signal CLK to the counter 206, the sample hold circuit 211, and the selector 213.

As described above, in the fifth embodiment, the frequency divider 205 is connected to the subsequent stage of the digitally-controlled oscillator 204. As a result, it is possible to reduce the operating frequency of the counter 206 and the time domain ADC 207 and reduce the power consumption.

Note that, in the embodiments described above, an example is described in which the counter 206 is provided in the ADPLL to be used for an initial frequency adjustment, but the counter 206 need not necessarily be provided. For example, a driver and a phase frequency detector (PFD) may be provided instead of the counter 206.

### 6. Sixth Embodiment

In the first embodiment described above, the voltage of the clock signal CLK sub-sampled by the sample hold circuit 211 is converted into the time difference by the voltage-to-time converter 212, and the time difference is detected by the time-to-digital converter TDC. In a sixth embodiment, a phase-locked circuit is applied to an imaging device.

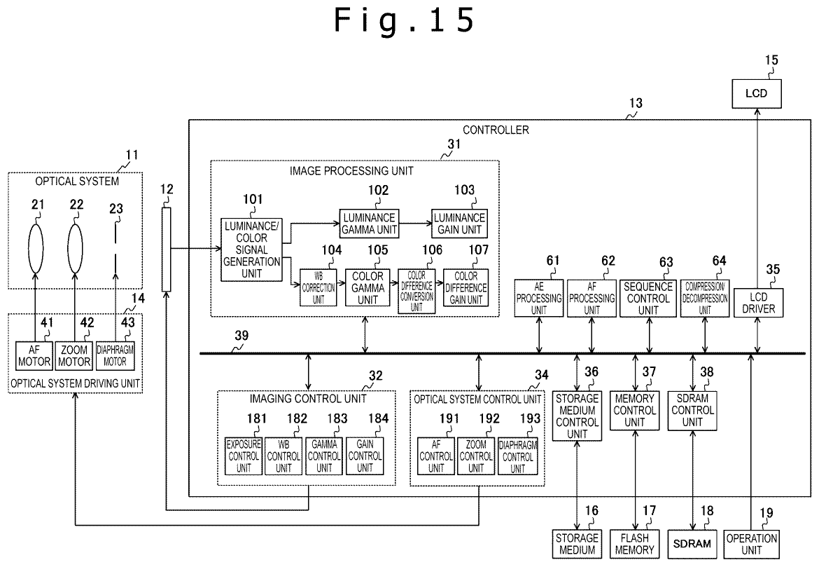

FIG. 15 is a block diagram depicting a configuration example of an imaging device according to the sixth embodiment.

In this drawing, the imaging device includes an optical system 11, a solid-state imaging device 12, a controller 13, an optical system driving unit 14, and a liquid crystal display (LCD) 15. The imaging device further includes a storage medium 16, a flash memory 17, a synchronous dynamic random access memory (SDRAM) 18, and an operation unit 19. Note that the imaging device may be used as a single body, may be incorporated into a mobile terminal such as a smartphone, may be incorporated into an authentication device or a monitoring device, or may be incorporated into an electric vehicle (EV) or a drone.

The optical system 11 forms an optical image on an imaging surface of the solid-state imaging device 12. The optical system 11 includes a focus lens 21, a zoom lens 22, and a diaphragm 23. The focus lens 21 adjusts a focus position on the imaging surface of the solid-state imaging device 12. The zoom lens 22 adjusts the magnification of a subject image formed on the imaging surface. The diaphragm 23 adjusts an amount of light incident on the imaging surface of the solid-state imaging device 12.

The solid-state imaging device 12 detects an optical image formed on the imaging surface and converts the detected optical image into an electric signal for each pixel, digitizes a pixel signal corresponding to an amount of light of the optical image, and outputs the digitized pixel signal. The solid-state imaging device 12 is, for example, a complementary metal oxide semiconductor (CMOS) sensor. Note that, to generate a clock signal for setting an operation timing of the solid-state imaging device 12, the phase-locked circuit according to any one of the first to fifth embodiments described above can be used.

The controller 13 integrally controls the entire imaging device. The controller 13 may include a processor such as a central processing unit (CPU) and a graphics processing unit (GPU). The processor may be a single-core processor or a multi-core processor. The controller 13 may include a hardware circuit (for example, a field-programmable gate array (FPGA) or an application specific integrated circuit (ASIC)) such as an accelerator that performs a part of the processing. Note that the phase-locked circuit according to any one of the first to fifth embodiments described above can be used to generate a clock signal for operating the controller 13.

The controller 13 includes an image processing unit 31, an imaging control unit 32, an optical system control unit 34, an LCD driver 35, a storage medium control unit 36, a flash memory control unit 37, and an SDRAM control unit 38. The controller 13 further includes an auto exposure (AE) processing unit 61, an auto focus (AF) processing unit 62, a sequence control unit 63, and a compression/decompression unit 64. The image processing unit 31, the imaging control unit 32, the optical system control unit 34, the LCD driver 35, the storage medium control unit 36, the flash memory control unit 37, the SDRAM control unit 38, the AE processing unit 61, the AF processing unit 62, the sequence control unit 63, and the compression/decompression unit 64 are connected to each other via a bus 39.

The image processing unit 31 implements image processing on the basis of the pixel signal generated by the solid-state imaging device 12. The image processing unit 31 includes a luminance/color signal generation unit 101, a luminance gamma unit 102, a luminance gain unit 103, a white balance (WB) correction unit 104, a color gamma unit 105, a color difference conversion unit 106, and a color difference gain unit 107.

The luminance/color signal generation unit 101 performs a matrix operation on the basis of the pixel signal generated by the solid-state imaging device 12, and generates a luminance signal and a color signal. The luminance signal may indicate, for example, a luminance value of each pixel. The color signal may indicate, for example, the magnitude of the RGB components for each pixel.

The luminance gamma unit 102 corrects the luminance of the luminance signal in accordance with the display characteristics of an image. For example, the luminance gamma unit 102 may correct the luminance of the luminance signal in accordance with the luminance characteristics of the LCD 15. The luminance gain unit 103 performs gain processing of the luminance signal.

The WB correction unit 104 corrects the white balance of the color signal. The color gamma unit 105 corrects the color tone of the color signal in accordance with the display characteristics of the image. For example, the color gamma unit 105 may correct the color tone of the color signal in accordance with the color characteristics of the LCD 15. The color difference conversion unit 106 converts the color signal of the RGB composition into a color difference signal on the basis of the matrix operation. The color difference gain unit 107 performs gain processing of the color difference signal.

The imaging control unit 32 controls imaging of the solid-state imaging device 12. The imaging control unit 32 includes an exposure control unit 181, a WB control unit 182, a gamma control unit 183, and a gain control unit 184.

The exposure control unit 181 controls exposure of the solid-state imaging device 12. At this time, the exposure control unit 181 can control an exposure time, an exposure amount, a shutter timing, and the like of the solid-state imaging device 12, for example, on the basis of a processing result of the AE processing unit 61. The exposure control unit 181 can use an AE evaluation value as the processing result of the AE processing unit 61.

The WB control unit 182 controls a gain amount of each of the RGB components of the WB correction unit 104 on the basis of input information input via the operation unit 19. The gamma control unit 183 controls the gamma characteristics of the luminance gamma unit 102 with respect to the luminance signal, and the gamma characteristics of the color gamma unit 105 with respect to the color signal, on the basis of the input information input via the operation unit 19. The gain control unit 184 controls gain of the luminance gain unit 103 with respect to the luminance signal, and gain of the color difference gain unit 107 with respect to the color difference signal, on the basis of the input information input via the operation unit 19.

The optical system control unit 34 controls driving of the optical system driving unit 14 on the basis of the processing result of the AE processing unit 61 and a processing result of the AF processing unit 62. The optical system control unit 34 includes an AF control unit 191, a zoom control unit 192, and a diaphragm control unit 193. The AF control unit 191 drives an AF motor 41 on the basis of the processing result of the AF processing unit 62. The AF control unit 191 can use an AF evaluation value as the processing result of the AF processing unit 62. The zoom control unit 192 drives a zoom motor 42 on the basis of a zoom operation of the operation unit 19. The diaphragm control unit 193 drives a diaphragm motor 43 on the basis of the processing result of the AE processing unit 61. The diaphragm control unit 193 can use the AE evaluation value as the processing result of the AE processing unit 61.

The LCD driver 35 drives the LCD 15. The LCD driver 35 converts image data processed by the image processing unit 31 or image data decompressed by the compression/decompression unit 64 into a video signal, and displays an image on the LCD 15 on the basis of the video signal.

The storage medium control unit 36 controls reading and writing of data from and to the storage medium 16. The flash memory control unit 37 controls reading and writing of data from and to the flash memory 17. The SDRAM control unit 38 controls reading and writing of data from and to the SDRAM 18.

The AE processing unit 61 calculates the AE evaluation value for each predetermined region of the image data generated by the solid-state imaging device 12. The AF processing unit 62 calculates the AF evaluation value for each predetermined region of the image data generated by the solid-state imaging device 12.

The sequence control unit 63 systematically controls processing of the imaging device. At this time, the sequence control unit 63 can control a series of processing steps from when the image data generated by the solid-state imaging device 12 is subjected to image processing to when the image data is displayed on the LCD 15. The sequence control unit 63 can also control a series of processing steps from when the image data generated by the solid-state imaging device 12 is subjected to the image processing and then compressed by the compression/decompression unit 64 to when the image data is stored in the storage medium 16. Further, the sequence control unit 63 can perform interruption processing on the basis of an operation of the operation unit 19.

The compression/decompression unit 64 compresses or decompresses the image data subjected to the image processing by the image processing unit 31 using a compression method such as a joint photographic experts group (JPEG) method.

The optical system driving unit 14 drives the optical system 11 on the basis of the control from the optical system control unit 34. The optical system driving unit 14 includes the AF motor 41, the zoom motor 42, and the diaphragm motor 43. The AF motor 41 moves the focus lens 21 in an optical axis direction on the basis of the control from the AF control unit 191. The zoom motor 42 moves the zoom lens 22 in the optical axis direction on the basis of the control from the zoom control unit 192. The diaphragm motor 43 adjusts the aperture diameter of the diaphragm 23 on the basis of the control from the diaphragm control unit 193.

The LCD 15 displays a captured image and displays various types of information for supporting an imaging operation.

The storage medium 16 stores the captured image captured by the imaging device, and the like. The storage medium 16 may be detachable. The storage medium 16 may be, for example, a memory card or a universal serial bus (USB) memory.

The flash memory 17 stores various control programs executed by the controller 13, parameters used for executing the various control programs, and the like.

The SDRAM 18 temporarily stores data generated in the processing of the controller 13. The SDRAM 18 may include a buffer memory for storing the image data for one frame.

The operation unit 19 provides a user interface for operating the imaging device. The operation unit 19 may include, for example, a button, a dial, and a switch provided in the imaging device. The operation unit 19 may be constituted by a touch panel together with the LCD 15.

Note that, depending on the form of a camera, the camera may not have some of the above-described functions, or conversely, may further have a function that is not disclosed herein.

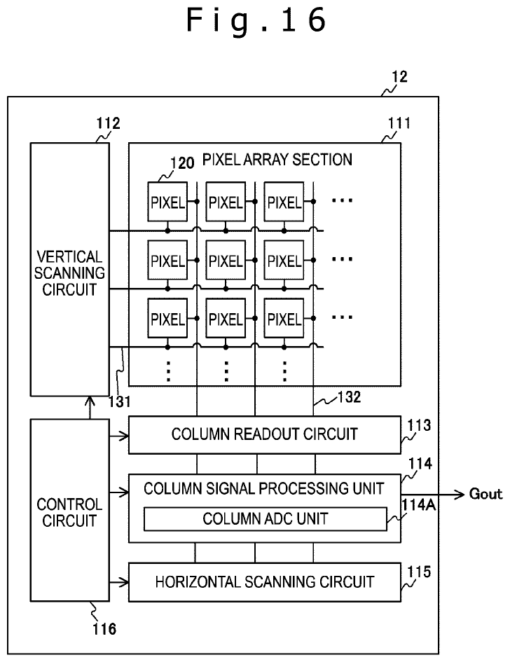

FIG. 16 is a block diagram depicting a configuration example of the solid-state imaging device according to the sixth embodiment.

In this drawing, the solid-state imaging device 12 includes a pixel array section 111, a vertical scanning circuit 112, a column readout circuit 113, a column signal processing unit 114, a horizontal scanning circuit 115, and a control circuit 116.

The pixel array section 111 includes a plurality of pixels 120. The pixels 120 are arrayed in a matrix in a row direction (also referred to as a horizontal direction) and a column direction (also referred to as a vertical direction). Each of the pixels 120 can form a source follower with the column readout circuit 113, during signal readout. Each of the pixels 120 is connected to a horizontal drive line 131 on a per row basis, and is connected to a vertical signal line 132 on a per column basis. The horizontal drive line 131 drives each of the pixels 120 on a per row basis, during signal readout from each of the pixels 120. The vertical signal line 132 transmits a potential based on the current flowing during the signal readout from the pixel 120, to the column signal processing unit 114 on a per column basis.

The vertical scanning circuit 112 scans, in the column direction, the pixels 120 to be read out. The vertical scanning circuit 112 may be constituted by using a vertical register.

The column readout circuit 113 can form a source follower with each of the pixels 120 during the signal readout from each of the pixels 120. At this time, the column readout circuit 113 can change the potential of the vertical signal line 132 on the basis of charges held in the pixel 120.

The column signal processing unit 114 processes signals transmitted from each of the pixels 120 in the column direction. For example, the column signal processing unit 114 can implement correlated double sampling (CDS) processing on the basis of the signals transmitted from each of the pixels 120 in the column direction. Further, the column signal processing unit 114 can implement analog-to-digital (AD) conversion processing on the basis of the signals transmitted from each of the pixels 120 in the column direction and can output an imaging signal Gout.

The column signal processing unit 114 includes a column ADC unit 114A. The column ADC unit 114A can perform AD conversion processing in parallel on a per column basis. At this time, the column ADC unit 114A can perform AD conversion on a per column basis, on the basis of a comparison result between the pixel signal read out from the pixel 120 and a reference signal.

The horizontal scanning circuit 115 scans, in the row direction, the pixels 120 to be read. The horizontal scanning circuit 115 may be constituted by using a horizontal register.

The control circuit 116 controls the vertical scanning circuit 112, the column readout circuit 113, the column signal processing unit 114, and the horizontal scanning circuit 115. For example, the control circuit 116 can control a scanning timing in the column direction, a scanning timing in the row direction, an operation timing of the column readout circuit 113, and a processing timing of the column signal processing unit 114.

### 7. Seventh Embodiment

In the first embodiment described above, the phase-locked circuit is applied to the imaging device. In this seventh embodiment, a semiconductor chip provided with a pixel array section including pixels arrayed in a matrix is layered.

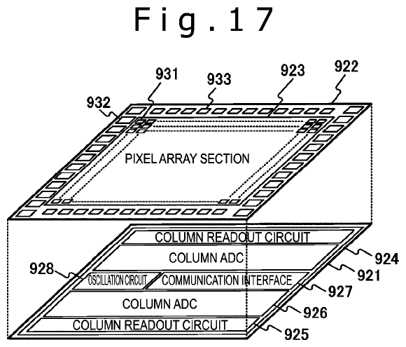

FIG. 17 is a perspective view depicting a layering example of the pixel array section according to the seventh embodiment.

In this drawing, the solid-state imaging device includes semiconductor chips 921 and 922. The semiconductor chip 922 is layered on the semiconductor chip 921.

A pixel array section 923 is formed on the semiconductor chip 922. In the pixel array section 923, pixels 931 are disposed in a matrix in the row direction and the column direction. A pad electrode 932 and a via electrode 933 are formed around the pixel array section 923. The via electrode 933 penetrates the semiconductor chip 922 and can electrically connect the semiconductor chips 921 and 922 to each other.

A peripheral circuit 924 is formed on the semiconductor chip 921. The peripheral circuit 924 includes a column readout circuit 925, a column ADC 926, a communication interface 927, and an oscillation circuit 928. The column readout circuit 925 and the column ADC 926 may be formed so as to correspond to positions on both sides of the pixel array section 923 in the column direction. The oscillator circuit 928 may include the phase-locked circuit according to any one of the first to fifth embodiments.

The semiconductor chips 921 and 922 may be directly bonded to each other. Hybrid bonding may be used for the direct bonding between the semiconductor chips 921 and 922. At this time, the semiconductor chips 921 and 922 may be electrically connected to each other via a Cu—Cu connection. The material of a semiconductor substrate used for the semiconductor chips 921 and 922 may be Si, may be InGaAs, or may be InP.

As described above, in the sixth embodiment described above, the semiconductor chip 922 on which the pixel array section 923 is formed is layered on the semiconductor chip 921 on which the peripheral circuit 924 is formed. As a result, it is possible to increase the sensitivity of the solid-state imaging device while suppressing an increase in a mounting area of the semiconductor chips on which the solid-state imaging device is formed.

### 7. Application Example of Mobile Body

The technology according to the present disclosure (present technology) can be applied to various products. For example, the technology according to the present disclosure may be implemented as a device mounted on any type of mobile bodies such as a vehicle, an electric vehicle, a hybrid electric vehicle, a motorcycle, a bicycle, a personal mobility, an airplane, a drone, a ship, and a robot.

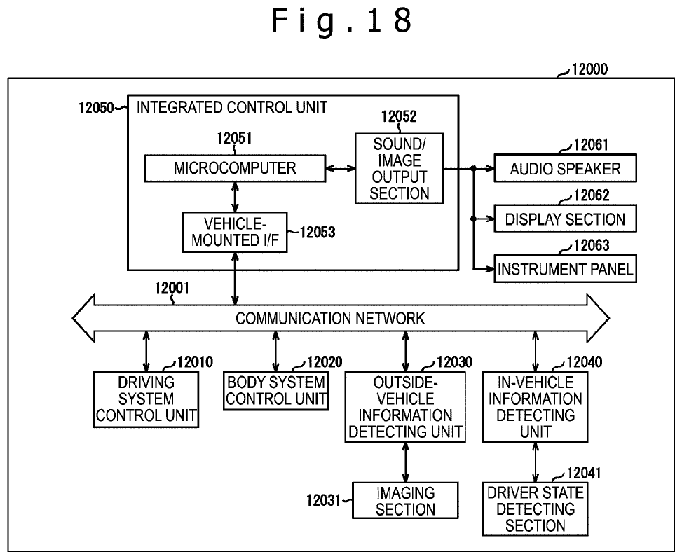

FIG. 18 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 18, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 18, an audio speaker 12061, a display section 12062, and an instrument panel 12063 are illustrated as the output device. The display section 12062 may, for example, include at least one of an on-board display and a head-up display.

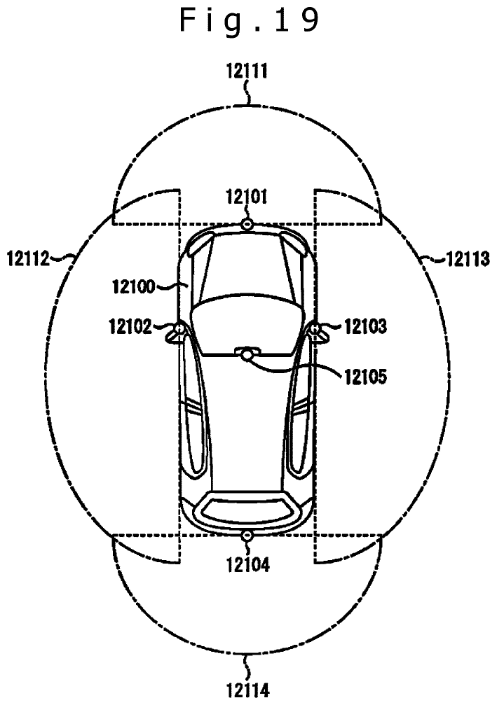

FIG. 19 is a diagram depicting an example of the installation position of the imaging section 12031.

In FIG. 19, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 19 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. Among the configurations described above, the technology according to the present disclosure can be applied to the driving system control unit 12010, the body system control unit 12020, the outside-vehicle information detecting unit 12030, the in-vehicle information detecting unit 12040, the integrated control unit 12050, and the imaging section 12031. Specifically, for example, the phase-locked circuit of the embodiment described above can be applied to the driving system control unit 12010, the body system control unit 12020, the outside-vehicle information detecting unit 12030, the in-vehicle information detecting unit 12040, the integrated control unit 12050, and the imaging section 12031. By applying the technology according to the present disclosure to the vehicle control system 12000, it is possible to improve the time resolution in digital processing.

Note that the phase-locked circuit according to any one of the first to fifth embodiments described above may be applied to an electronic circuit used in a communication device, a display device, a data processing device, a control device, a measurement device, a printing device, or the like, in addition to being applied to an imaging device.

Further, the embodiments described above are examples for embodying the present technology, and the matters according to the embodiments and the matters specifying the invention in the scope of claims have correspondence relationships, respectively. Similarly, the matters specifying the invention in the scope of claims and the matters in the embodiments of the present technology to which the same names are given have correspondence relationships, respectively. However, the present technology is not limited to the embodiments, and can be embodied by applying various modifications to the embodiments without departing from the gist of the present technology. Further, the effects described in the present specification are merely examples and are not limited, and other effects may be provided.

Note that the present technology may also have the following configurations.
(1) A phase-locked circuit includes a sample hold circuit configured to sub-sample an input signal, on the basis of a reference signal, a voltage-to-time converter configured to convert a voltage of the input signal sub-sampled by the sample hold circuit into a time difference, and a time-to-digital converter configured to detect the time difference converted by the voltage-to-time converter.
(2) In the phase-locked circuit according to (1) described above, the sample hold circuit, the voltage-to-time converter, and the time-to-digital converter constitute a time domain analog to digital converter (ADC).
(3) In the phase-locked circuit according to (2) described above, a time resolution of the time domain ADC is higher than a time resolution of the time-to-digital converter.
(4) The phase-locked circuit according to any one of (1) to (3) described above, further includes a digitally-controlled oscillator configured to generate the input signal.
(5) The phase-locked circuit according to (4) described above further includes an accumulator configured to set a count-up value for each cycle of the reference signal, on the basis of a frequency command word (FCW), a counter configured to count up for each cycle of the input signal, an arithmetic unit configured to subtract an output of the counter and an output of the voltage-to-time converter from an output of the accumulator, and a loop filter configured to limit a band of an input to the digitally-controlled oscillator.
(6) The phase-locked circuit according to (4) or (5) described above further includes a frequency divider configured to frequency-divide the input signal generated by the digitally-controlled oscillator.
(7) The phase-locked circuit according to any one of (1) to (6) described above further includes a digital-to-time converter configured to delay the reference signal.
(8) The phase-locked circuit according to any one of (1) to (7) described above further includes a selector configured to switch an input to the time-to-digital converter, between an input of the time difference converted by the voltage-to-time converter and an input of the reference signal and the input signal.
(9) In the phase-locked circuit according to (8) described above, the selector inputs the time difference converted by the voltage-to-time converter to the time-to-digital converter when a sub-sampling mode is specified, and inputs the reference signal and the input signal to the time-to-digital converter when a normal mode is specified.
(10) In the phase-locked circuit according to (9) described above, the normal mode is intermittently operated during operation in the sub-sampling mode.
(11) In the phase-locked circuit according to any one of (1) to (10) described above, calibration of a phase-locked loop is performed.
(12) An imaging device includes an imaging section including a plurality of pixels and a phase-locked circuit configured to generate a clock signal for setting an operation timing of the imaging section. The phase-locked circuit includes a sample hold circuit configured to sub-sample the clock signal, on the basis of a reference clock, a voltage-to-time converter configured to convert a voltage of the clock signal sub-sampled by the sample hold circuit into a time difference, and a time-to-digital converter configured to detect the time difference converted by the voltage-to-time converter.
(13) An electronic circuit includes a circuit unit configured to operate on the basis of a clock signal and a phase-locked circuit configured to generate a clock signal for setting an operation timing of the circuit unit. The phase-locked circuit includes a sample hold circuit configured to sub-sample the clock signal, on the basis of a reference clock, a voltage-to-time converter configured to convert a voltage of the clock signal sub-sampled by the sample hold circuit into a time difference, and a time-to-digital converter configured to detect the time difference converted by the voltage-to-time converter.

### REFERENCE SIGNS LIST

200 ADPLL
201 Accumulator
202 Arithmetic unit
203 Loop filter
204 Digitally-controlled oscillator
206 Counter
207 Time domain ADC
208 Digital-to-time converter
209 Control unit
211 Sample hold circuit
212 Voltage-to-time converter
213 Selector
214 Time-to-digital converter

1. A phase-locked circuit comprising:
a sample hold circuit configured to sub-sample an input signal, on the basis of a reference signal;
a voltage-to-time converter configured to convert a voltage of the input signal sub-sampled by the sample hold circuit into a time difference; and
a time-to-digital converter configured to detect the time difference converted by the voltage-to-time converter.

2. The phase-locked circuit according to claim 1, wherein
the sample hold circuit, the voltage-to-time converter, and the time-to-digital converter constitute a time domain analog to digital converter (ADC).

3. The phase-locked circuit according to claim 2, wherein
a time resolution of the time domain ADC is higher than a time resolution of the time-to-digital converter.

4. The phase-locked circuit according to claim 1, further comprising:
a digitally-controlled oscillator configured to generate the input signal.

5. The phase-locked circuit according to claim 4, further comprising:
an accumulator configured to set a count-up value for each cycle of the reference signal, on the basis of a frequency command word (FCW);
a counter configured to count up for each cycle of the input signal;
an arithmetic unit configured to subtract an output of the counter and an output of the voltage-to-time converter from an output of the accumulator; and
a loop filter configured to limit a band of an input to the digitally-controlled oscillator.

6. The phase-locked circuit according to claim 4, further comprising:
a frequency divider configured to frequency-divide the input signal generated by the digitally-controlled oscillator.

7. The phase-locked circuit according to claim 1, further comprising:
a digital-to-time converter configured to delay the reference signal.

8. The phase-locked circuit according to claim 1, further comprising:
a selector configured to switch an input to the time-to-digital converter, between an input of the time difference converted by the voltage-to-time converter and an input of the reference signal and the input signal.

9. The phase-locked circuit according to claim 8, wherein
the selector
inputs the time difference converted by the voltage-to-time converter to the time-to-digital converter when a sub-sampling mode is specified, and
inputs the reference signal and the input signal to the time-to-digital converter when a normal mode is specified.

10. The phase-locked circuit according to claim 9, wherein
the normal mode is intermittently operated during operation in the sub-sampling mode.

11. The phase-locked circuit according to claim 1, wherein
calibration of a phase-locked loop is performed.

12. An imaging device comprising:
an imaging section including a plurality of pixels; and
a phase-locked circuit configured to generate a clock signal for setting an operation timing of the imaging section, wherein
the phase-locked circuit includes
a sample hold circuit configured to sub-sample the clock signal, on the basis of a reference clock,
a voltage-to-time converter configured to convert a voltage of the clock signal sub-sampled by the sample hold circuit into a time difference, and
a time-to-digital converter configured to detect the time difference converted by the voltage-to-time converter.

13. An electronic circuit comprising:
a circuit unit configured to operate on the basis of a clock signal; and
a phase-locked circuit configured to generate a clock signal for setting an operation timing of the circuit unit, wherein
the phase-locked circuit includes
a sample hold circuit configured to sub-sample the clock signal, on the basis of a reference clock,
a voltage-to-time converter configured to convert a voltage of the clock signal sub-sampled by the sample hold circuit into a time difference, and
a time-to-digital converter configured to detect the time difference converted by the voltage-to-time converter.
